(19) United States
(12) Patent Application Publication
(10) Pub. No.: US 2010/0225402 A1
(43) Pub. Date: Sep. 9, 2010

(54) VCO TUNING WITH TEMPERATURE COMPENSATION

(75) Inventors: Jeongsik Yang, Cupertino, CA (US); Jin Wook Kim, San Jose, CA (US); Sang-Oh Lee, Cupertino, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/400,658

(22) Filed: Mar. 9, 2009

(51) Int. Cl. H03L 7/00

(52) U.S. Cl. 331/10

(57) ABSTRACT

Techniques for setting a fine tuning input signal Vtune for a voltage-controlled oscillator (VCO) in a coarse tuning mode of the VCO. In an exemplary embodiment, the fine tuning input signal during coarse tuning mode is made temperature-dependent to account for possible variation of Vtune over temperature during fine tuning mode. Methods and apparatuses employing the techniques are further described.

### TECHNICAL FIELD

The disclosure relates to voltage-controlled oscillators (VCO's), and more particularly, to techniques for tuning VCO's in the presence of temperature change.

### BACKGROUND

A voltage-controlled oscillator (VCO) is an electrical oscillator designed to generate a signal having an oscillation frequency controlled by a voltage input signal. To ease tuning range requirements, VCO's are often designed to support a voltage input signal that includes both a coarse frequency tuning signal and a fine frequency tuning signal.

The coarse frequency tuning signal is typically determined by selecting an optimal coarse tuning signal during a coarse tuning mode, while setting the fine frequency tuning signal to a constant value. Subsequently, the fine frequency tuning signal is dynamically adjusted during a fine tuning mode, while setting the coarse frequency tuning signal to the earlier determined optimal coarse tuning signal.

During fine tuning mode, VCO temperature change may affect the level of the fine frequency tuning signal required to maintain a constant VCO output frequency. Such temperature change may undesirably cause the fine frequency tuning signal to exceed the linear input range of the VCO, especially when the VCO is operated using a low supply voltage.

It would be desirable to provide techniques for limiting the effects of temperature change on the VCO fine frequency tuning signal.

### SUMMARY

An aspect of the present disclosure provides a method for tuning an output frequency of a voltage-controlled oscillator (VCO), the method comprising setting a fine tuning signal Vtune for the VCO during a coarse tuning mode, and determining a preferred coarse tuning signal for the VCO during the coarse tuning mode, the method further comprising: sensing a temperature; during the coarse tuning mode; and setting the fine tuning input signal Vtune during the coarse tuning mode based on the sensed temperature.

Another aspect of the present disclosure provides an apparatus for tuning an output frequency of a voltage-controlled oscillator (VCO), the VCO accepting a fine tuning voltage Vtune and a coarse tuning signal for controlling the output frequency of the VCO, the apparatus comprising: a temperature sensor for measuring a temperature T; and a voltage generator for generating a voltage Vtune_coarse(T) based on the measured temperature T, the VCO accepting the voltage Vtune_coarse(T) as the fine tuning voltage Vtune during a coarse tuning mode of the VCO.

Yet another aspect of the present disclosure provides an apparatus for tuning an output frequency of a voltage-controlled oscillator (VCO), the VCO accepting a fine tuning voltage Vtune and a coarse tuning signal for controlling the output frequency of the VCO, the apparatus comprising: means for sensing a temperature; and means for setting the fine tuning input signal Vtune during the coarse tuning mode based on the sensed temperature.

Yet another aspect of the present disclosure provides a computer program product for tuning an output frequency of a voltage-controlled oscillator (VCO), the VCO accepting a fine tuning voltage Vtune and a coarse tuning signal for controlling the output frequency of the VCO, the product comprising: computer-readable media comprising code for causing a computer to sense a temperature; and computer-readable media comprising code for causing a computer to set the fine tuning input signal Vtune during the coarse tuning mode based on the sensed temperature.

### BRIEF DESCRIPTION OF DRAWINGS

FIG. 1 depicts a prior art frequency synthesizer employing a voltage-controlled oscillator (VCO).

FIG. 1A illustrates a flow diagram depicting the operation of the prior art frequency synthesizer.

FIG. 2 illustrates an example of the effects of temperature change on Vtune and VCO output frequency (f).

FIG. 3 depicts the combined effects of temperature and other factors contributing to the deviation of Vtune from Vtune_coarse during fine tuning mode.

FIG. 3A illustrates the effects of lower levels of supply voltage on the VCO linear range Vrange_linear.

FIG. 4 depicts an exemplary embodiment according to the present disclosure, wherein Vtune is an analog signal.

FIG. 4A depicts a V-T characteristic for mapping the VCO temperature T to a voltage Vtune_coarse(T).

FIG. 5 depicts the combined effects of temperature and other factors contributing to the deviation of Vtune from Vtune_coarse during fine tuning mode, for the frequency synthesizer depicted in FIG. 4.

FIG. 5A illustrates the case wherein the temperature T is the minimum expected operating temperature Tmin.

FIG. 5B illustrates the case wherein the temperature T is the maximum expected operating temperature Tmax.

FIG. 6 depicts an exemplary embodiment of a method according to the present disclosure.

### DETAILED DESCRIPTION

The detailed description set forth below in connection with the appended drawings is intended as a description of exemplary embodiments of the present invention and is not intended to represent the only exemplary embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein.

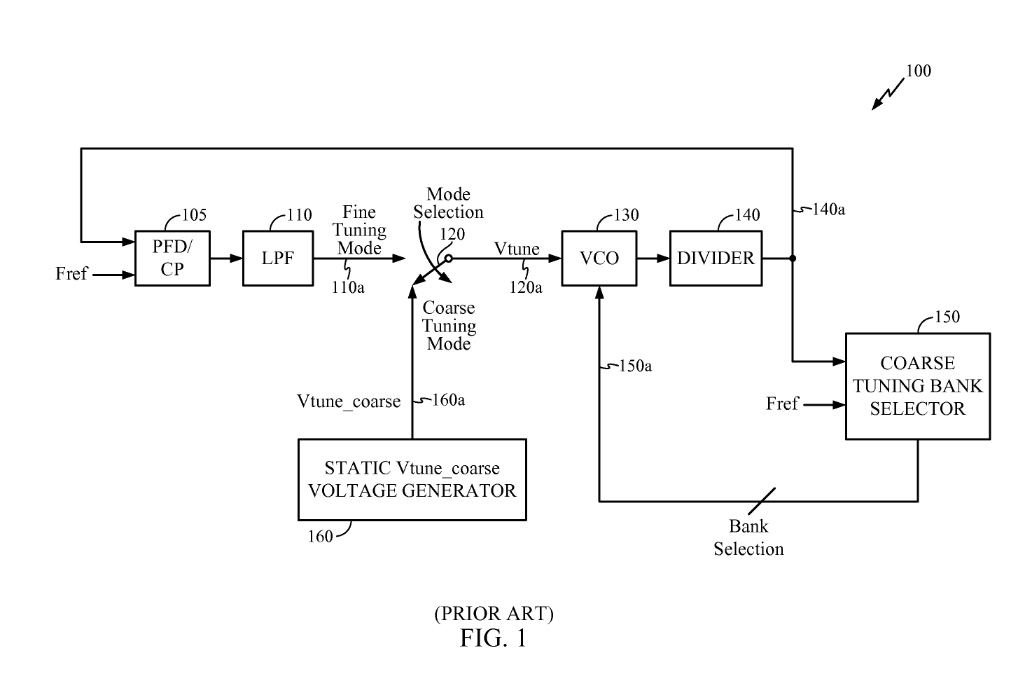

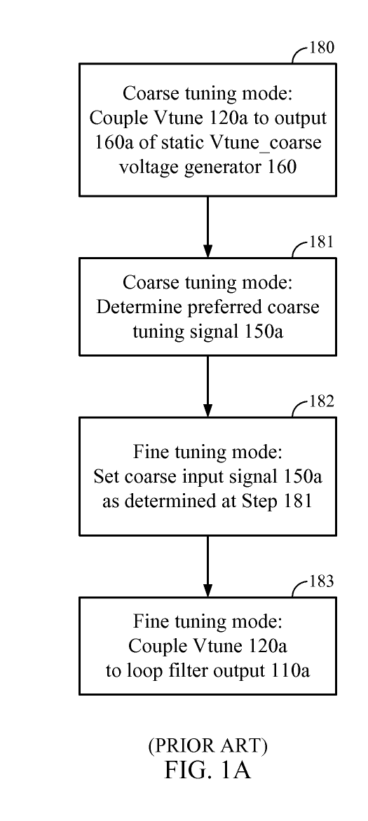

FIG. 1 depicts a simplified prior art frequency synthesizer 100 employing a voltage-controlled oscillator (VCO) 130. Note the frequency synthesizer 100 is depicted for illustrative purposes only, and is not meant to limit the scope of the present disclosure to any particular implementations of a frequency synthesizer. One of ordinary skill in the art will appreciate that an actual frequency synthesizer may employ fewer or more functional blocks than shown in FIG. 1.

To ease dynamic range requirements, the VCO 130 supports a voltage input signal that includes both a coarse frequency tuning signal 150a (or “coarse tuning signal”) and a fine frequency tuning signal 120a, or Vtune. To tune the VCO output frequency to a desired frequency, the operation of the frequency synthesizer 100 may be divided into a coarse tuning mode followed by a fine tuning mode. The VCO tuning process for the frequency synthesizer 100 is further described herein with reference to the flow diagram in FIG. 1A. Note the steps in FIG. 1A are depicted for illustrative purposes only, and are not meant to limit the scope of the present disclosure to the particular steps disclosed herein.

In FIG. 1A, the flow diagram commences with the coarse tuning mode. At step 180, the three-way switch 120 in FIG. 1 couples Vtune to a fixed voltage 160a, or Vtune_coarse, generated by a static Vtune_coarse voltage generator 160. This operates to keep Vtune well-defined during coarse tuning mode. In certain prior art implementations, the level of Vtune_coarse may be fixed at half the VCO supply voltage level VDD, to allow maximum variation of Vtune during normal operation of the frequency synthesizer 100.

At step 181, a coarse tuning mode bank selector 150 in FIG. 1 determines a preferred coarse tuning signal which produces a divider 140 output frequency that is closest to a reference frequency Fref. For example, the coarse tuning bank selector 150 may search through a plurality of settings of signal 150a to select an optimal setting of the coarse tuning signal. In certain prior art implementations, the signal 150a may selectively enable one or more capacitors in a capacitor bank (not shown) in the VCO 130. Coarse tuning mode may thus bring the VCO output frequency close to the desired frequency, to within the coarse precision offered by the minimum step size of the capacitor bank.

Upon completion of the coarse tuning mode, the frequency synthesizer 100 switches to a fine tuning mode at step 182. The coarse tuning mode bank selector 150 sets the coarse tuning signal 150a to be the preferred coarse tuning signal determined at step 181. At step 183, the switch 120 couples Vtune to the output 110a of a loop filter (LPF) 110, which is also coupled to a phase-frequency detector/charge pump (PFD/CP) 105. Collectively, the PFD/CP 105, LPF 110, VCO 130, and frequency divider 140 form a phase-locked loop (PLL) that allows the frequency of the divider output 140a to track the frequency Fref of a reference signal provided to the PFD/CP 105.

In certain implementations, if an additional frequency divider (not shown) is provided to further divide the divider output 140a prior to the PFD/CP 105, then the signal provided to the coarse tuning bank selector 150 need not be the same as the signal fed back to the PFD/CP 105. In that case, the reference frequencies provided to the coarse tuning bank selector 150 and the PFD/CP may be correspondingly different.

In certain implementations (not shown), additional modulation may be applied to the frequency or phase of a PLL output signal by, e.g., dynamically modulating the divider ratio, or employing other techniques well-known to one of ordinary skill in the art.

In certain implementations, the functionality of the coarse tuning bank selector 150 may be performed using a pulse counter and comparator (not shown). For example, the pulse counter may count the number of pulses in the VCO output signal over a period of time, and compare the number of counted pulses to a reference number of pulses based on a reference signal. The comparison gives an indication of whether the VCO output signal is slower or faster than the reference signal, which may be used to select the appropriate coarse tuning mode setting for the VCO 130. These and other implementations of a PLL are known to one of ordinary skill in the art, and are contemplated to be within the scope of the present disclosure.

In certain implementations, Vtune may be an analog signal directly coupled to, e.g., a variable capacitance element, such as a varactor. In alternative implementations, Vtune may be digitally specified, and be, e.g., directly coupled to a plurality of weighted capacitances in a capacitor bank. The techniques of the present disclosure are contemplated to be applicable to all such implementations of a VCO.

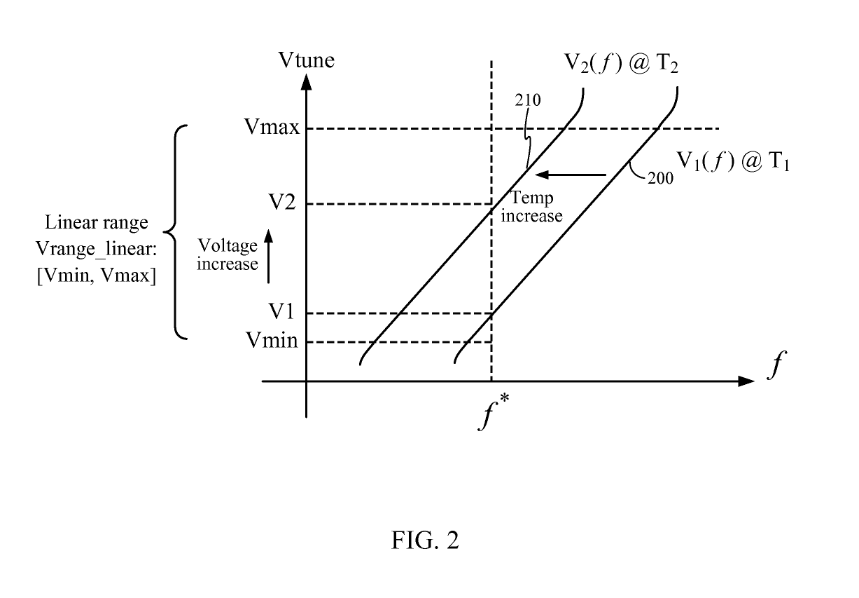

FIG. 2 illustrates an example of the effects of temperature change on Vtune and VCO output frequency (f). Note the temperature-voltage-frequency characteristics shown in FIG. 2 are for illustrative purposes only, and are not meant to restrict the scope of the present disclosure to any particular temperature-voltage-frequency characteristics depicted. The techniques of the present disclosure are contemplated to be applicable to any temperature-voltage-frequency characteristics.

In FIG. 2, a first voltage-frequency characteristic 200 illustrates a typical dependence of Vtune on VCO output frequency (f), given that the temperature (T) is fixed at a first level T1. Similarly, a second voltage-frequency characteristic 210 illustrates the dependence of Vtune on f, given that T is fixed at a second level T2 greater than the first level T1. Over a voltage range from Vmin to Vmax, denoted the “linear range” of the VCO, or Vrange_linear, the relationship of Vtune to f is generally linear, with Vtune directly proportional to f. During normal operation of a frequency synthesizer, it is usually desired to maintain Vtune within the linear range of the VCO.

FIG. 2 further illustrates that a rise in temperature (from T1 to T2) causes the voltage Vtune required to generate a single VCO output frequency f* to also rise (from V1 to V2). As a frequency synthesizer is usually designed to operate over a wide range of temperatures, the variations in Vtune over temperature must be accounted for to keep Vtune within the linear range.

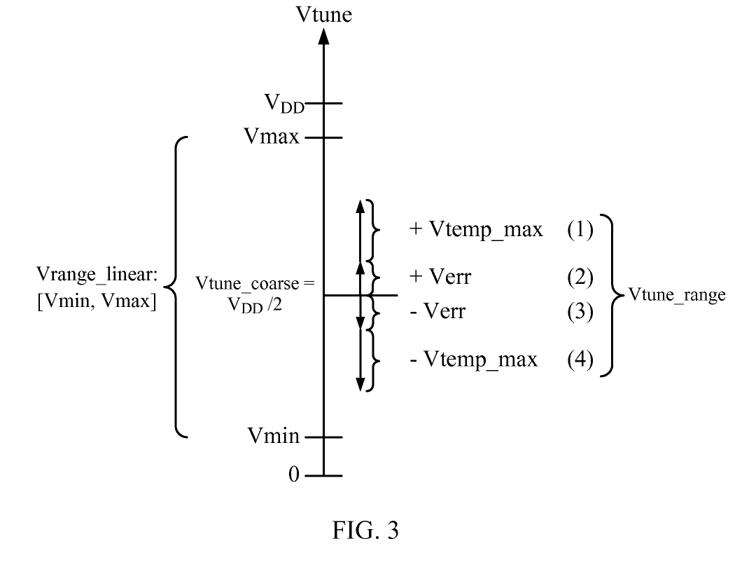

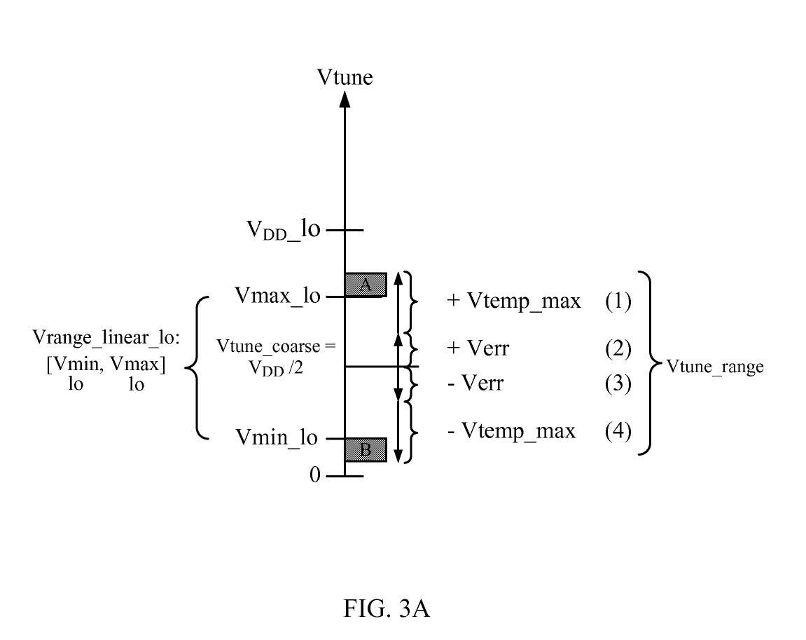

FIG. 3 depicts the combined effects of temperature and other factors contributing to the variation of Vtune during fine tuning mode. In FIG. 3, the linear range of the VCO, again defined by Vmin and Vmax, is depicted on a left vertical axis, and is shown relative to the supply voltage VDD of the VCO. Vtune_coarse is shown as a fixed level VDD/2, in accordance with prior art techniques for selecting Vtune_coarse.

One factor contributing to the deviation of Vtune from Vtune_coarse is the difference in precision between coarse tuning mode and fine tuning mode. In particular, the VCO output frequency after coarse tuning mode may generally be offset from the actual target frequency, e.g., by up to one-half of the coarse frequency step size of the capacitor bank used in the VCO. Therefore, during fine tuning mode, Vtune may be adjusted away from Vtune_coarse to allow the VCO output frequency to track the target frequency to within the resolution of the fine tuning mode. In FIG. 3, the possible variation in Vtune due to this adjustment, and any other variations in Vtune due to factors not explicitly enumerated herein, is denoted by Verr, with +Verr (2) denoting positive adjustment, and −Verr (3) denoting negative adjustment.

Another factor contributing to the deviation of Vtune from Vtune_coarse is any temperature change experienced by the VCO after switching from coarse tuning mode to fine tuning mode. In particular, as previously described with reference to FIG. 2, the level of Vtune for a single VCO output frequency may vary due to changes in the VCO temperature. In FIG. 3, the maximum positive variation in Vtune due to temperature change is denoted by +Vtemp_max (1), and the maximum negative variation is denoted by −Vtemp_max (4).

As an illustration of the effects of temperature change on Vtune, assume that the VCO temperature during coarse tuning mode is the minimum expected operating temperature, Tmin. In the subsequent fine tuning mode, if the VCO temperature increases to the maximum expected operating temperature, Tmax, then assuming the characteristics shown in FIG. 2, Vtune will be expected to increase by a corresponding amount Vtemp_max to maintain the same VCO target frequency, i.e., Vtune will change by +Vtemp_max (1).

Conversely, if the VCO temperature during coarse tuning mode is the maximum expected operating temperature, Tmax, and the VCO temperature decreases to the minimum expected operating temperature, Tmin, during fine tuning mode, then Vtune will be expected to decrease by a corresponding amount Vtemp_max, i.e., Vtune will change by −Vtemp_max (4).

Due to the factors described above, Vtune may generally vary during fine tuning mode from a minimum voltage level {Vtune_coarse−[(3)+(4)]} to a maximum voltage level {Vtune_coarse+[(1)+(2)]}. This range in voltage variation is also denoted as Vtune_range in FIG. 3. As a design consideration, to ensure linear operation of the VCO over an entire expected operating temperature range Tmin to Tmax, Vtune_range should lie entirely within Vrange_linear.

One of ordinary skill in the art will appreciate that, because the prior art frequency synthesizer 100 does not account for the actual VCO temperature during coarse tuning mode, both possible temperature-dependent variations in Vtune (i.e., increase by up to +Vtemp_max (3) and decrease by up to −Vtemp_max (4)) must be budgeted for in a robust circuit design.

As modern devices move toward employing lower supply voltages to save power, it becomes increasingly difficult to keep Vtune within the VCO linear operating range across temperature. In particular, FIG. 3A illustrates the effects of lower levels of supply voltage on the VCO linear range Vrange_linear. In FIG. 3A, the vertical axis shows a level of supply voltage VDD_lo that is lower than the level of supply voltage VDD shown in FIG. 3. The linear range Vrange_linear_lo of the VCO, defined by a lower limit Vmin_lo and an upper limit Vmax_lo, is correspondingly smaller than the linear range Vrange_linear shown in FIG. 3.

As the variation of Vtune with temperature is generally unaffected by a change in the supply voltage, the limits of Vtune_range are seen to exceed the limits of Vrange_linear_lo when the supply voltage is VDD_lo. In particular, a portion (A) of Vtune_range is higher than the upper limit Vmax_lo of Vrange_linear_lo, while a portion (B) of Vtune_range is lower than the lower limit Vmin_lo of Vrange_linear_lo. This leads to Vtune undesirably being outside the VCO linear range for some temperatures during fine tuning mode.

According to the present disclosure, techniques are provided to reduce the expected variation of Vtune across temperature, so that the VCO may reliably operate across temperature using reduced supply voltage levels.

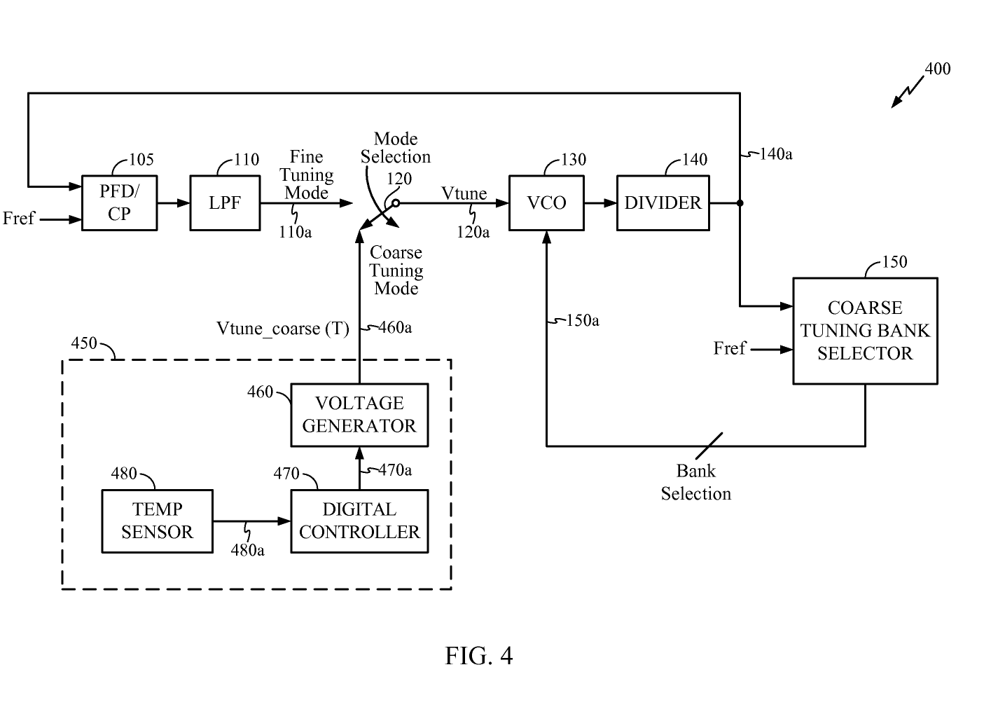

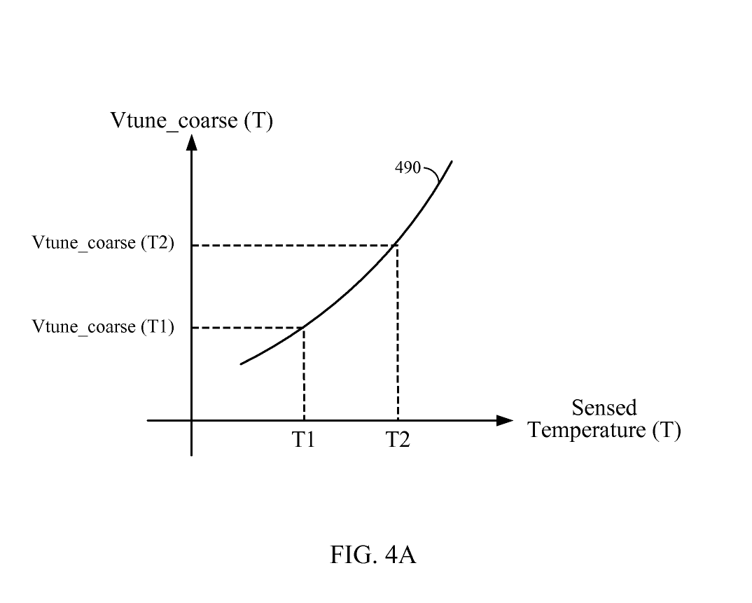

FIG. 4 depicts an exemplary embodiment according to the present disclosure, wherein Vtune is an analog signal. One of ordinary skill in the art will appreciate that while FIG. 4 depicts an exemplary embodiment wherein Vtune is an analog signal, the techniques of the present disclosure may be readily modified to accommodate embodiments wherein Vtune is a digital control signal. Such alternative exemplary embodiments are contemplated to be within the scope of the present disclosure.

In FIG. 4, a temperature sensor 480, a digital controller 470, and a voltage generator 460 collectively form a Vtune_coarse(T) voltage generator 450. In particular, the temperature sensor 480 senses the temperature (T), and outputs the sensed temperature as signal 480a. In an exemplary embodiment, the temperature sensor 480 may directly measure the temperature of the VCO circuit 130. In alternative exemplary embodiments, the temperature sensor 480 may measure an ambient temperature as an approximation to the temperature of the VCO circuit 130.

The digital controller 470 maps the signal 480a to a digital value of Vtune_coarse(T), or signal 470a. A voltage generator 460 converts signal 470a to an analog voltage level Vtune_coarse(T), or signal 460a, which is provided to the VCO 130 as Vtune during coarse tuning mode. As the digital controller 470 adjusts the value of signal 470a based on the sensed temperature 480a, Vtune_coarse(T) is effectively a temperature-adjusted level of Vtune_coarse. As further described hereinbelow, providing such a temperature-adjusted Vtune_coarse(T) during coarse tuning mode may help reduce the expected variation of Vtune over temperature during fine tuning mode.

In an exemplary embodiment, the elements of the generator 450 collectively function to map the sensed temperature T to a voltage Vtune_coarse(T) according to a V-T characteristic, such as that shown in FIG. 4A. In FIG. 4A, the V-T characteristic 490 monotonically maps increasing temperatures T to increasing values of Vtune_coarse(T). For example, when the temperature T is a first value T1, Vtune_coarse(T) may be set to a value Vtune_coarse(T1). When the temperature T is a second value T2 higher than T1, Vtune_coarse(T) may be set to a value Vtune_coarse(T2) higher than Vtune_coarse(T1).

Note the V-T characteristic 490 depicted in FIG. 4A is shown for illustrative purposes only, and is not meant to limit the scope of the present disclosure to any particular characteristic shown. One of ordinary skill in the art will appreciate that the techniques of the present disclosure may accommodate an arbitrary expected dependence of control voltage Vtune(T) on temperature. In an exemplary embodiment, the actual V-T characteristic used may be derived based on lab measurements of the particular VCO circuitry, or computer simulations, or any other method known to one of ordinary skill in the art.

In an exemplary embodiment (not shown), a VCO V-T characteristic such as characteristic 490 in FIG. 4A may be digitally stored in hardware in the form of a look-up table. For example, digital controller 470 in FIG. 4 may include a memory circuit (not shown) that implements a look-up table mapping particular values of temperature T, or signal 480a, to particular values of Vtune_coarse(T), or signal 470a. In alternative exemplary embodiments (not shown), the mapping may be accomplished by programming digital controller 470 to digitally compute a given V-T characteristic, or to use any other functional mapping techniques known to one of ordinary skill in the art. Such exemplary embodiments are contemplated to be within the scope of the present disclosure.

In FIG. 4, the temperature sensor 480, digital controller 470, and voltage generator 460 have been shown as separate logical blocks to clarify their functional roles. In an actual exemplary embodiment, the functions represented by these blocks may be integrated into the functionality of a single circuitry block, or divided among even more blocks than shown. Furthermore, the generator 450 may be integrated on the same chip as the rest of the frequency synthesizer 400, or the generator 450 may be provided on a separate chip interfacing with the frequency synthesizer 400. Such exemplary embodiments are also contemplated to be within the scope of the present disclosure.

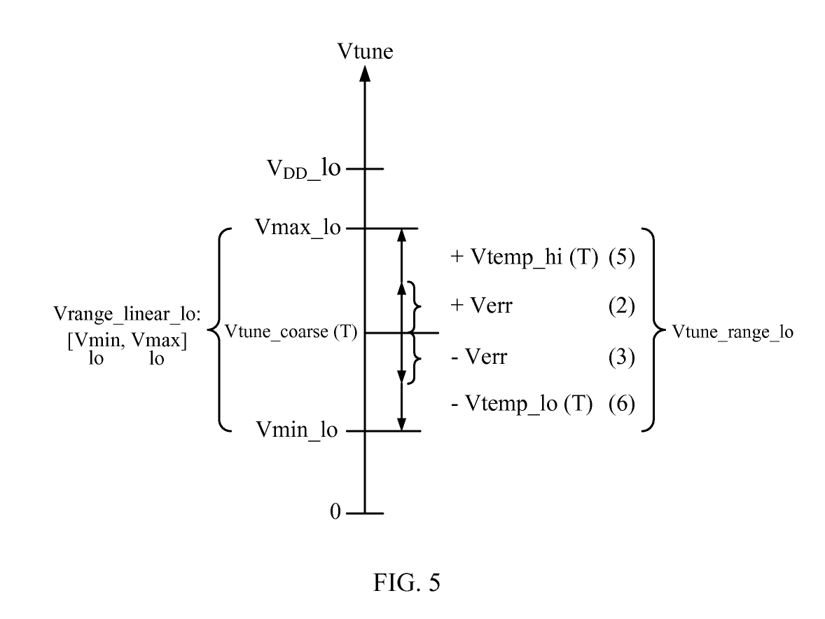

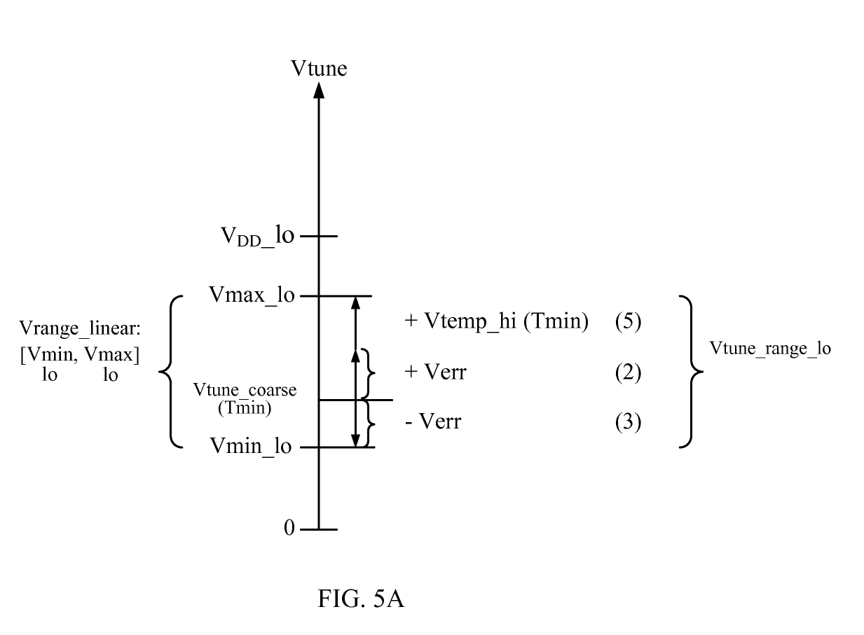

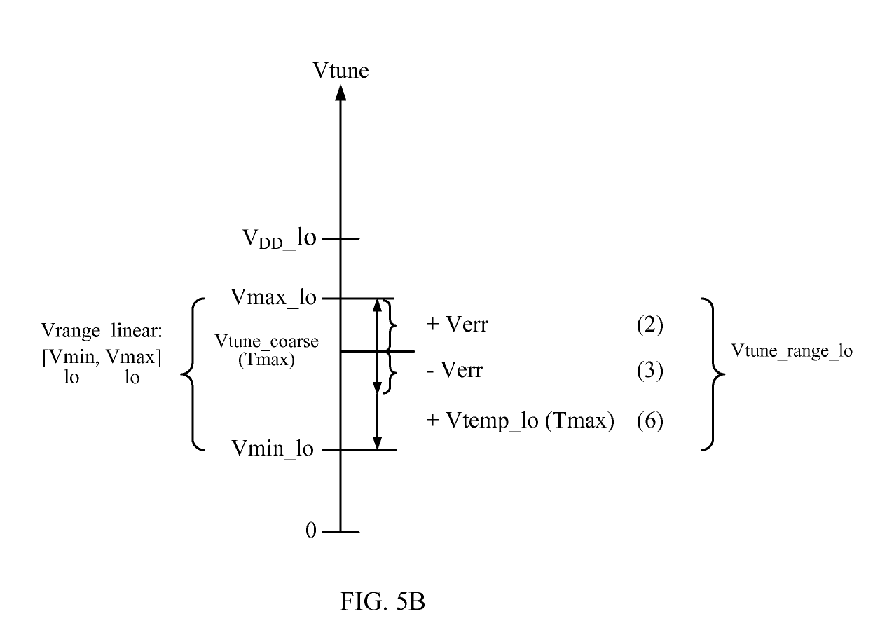

FIG. 5 depicts the combined effects of temperature and other factors contributing to the deviation of Vtune from Vtune_coarse during fine tuning mode, for the frequency synthesizer 400 depicted in FIG. 4. In FIG. 5, the frequency synthesizer 400 is assumed to operate using a supply voltage VDD_lo, and thus the VCO linear range is the same as the range Vrange_linear_lo earlier depicted with reference to FIG. 3A.

Immediately after the frequency synthesizer 400 switches from coarse tuning mode to fine tuning mode, the voltage Vtune may deviate from the initial coarse tuning mode level of Vtune_coarse(T) by up to +Verr (2) and −Verr (3), due to the aforementioned frequency bank step size and other factors not explicitly enumerated herein. These deviations are identical to those depicted in FIGS. 3 and 3A for the prior art frequency synthesizer 100.

Furthermore, due to subsequent temperature variation during fine tuning mode, Vtune may further vary from Vtune_coarse(T) by a maximum positive adjustment +Vtemp_hi(T) (5), and a maximum negative adjustment −Vtemp_lo(T) (6).

For example, assume that the VCO temperature during coarse tuning mode is the minimum expected operating temperature Tmin, as illustrated in FIG. 5A. In this case, Vtune_coarse(T) is correspondingly set to a minimum level Vtune_coarse(Tmin). In the subsequent fine tuning mode, if the VCO temperature increases to the maximum expected operating temperature Tmax, then Vtune may also be expected to increase by an amount Vtemp_hi(T) (5) to maintain the same VCO target frequency, i.e., Vtune is adjusted upward by +Vtemp_hi (5). However, as the VCO temperature during coarse tuning mode was already determined to be the minimum temperature Tmin, Vtune is not expected to decrease beyond the initial value of Vtune_coarse(Tmin) over temperature (to within the error margin −Verr (3)). Thus the total variation of Vtune for frequency synthesizer 400 during fine tuning mode, i.e., Vtune_range_lo, may be computed as ranging from a minimum value {Vtune_coarse(Tmin)−(3)} to a maximum value {Vtune_coarse(Tmin)+(2)+(5)}. Assuming the parameter (5) is approximately equal to the parameter (1) in FIG. 3, Vtune_range_lo is thus seen to be less than Vtune_range.

Similarly, if the VCO temperature during coarse tuning mode is the maximum expected operating temperature Tmax, as shown in FIG. 5B, one of ordinary skill in the art will appreciate based on the preceding description that the corresponding Vtune_range_lo may be computed as ranging from a minimum value {Vtune_coarse(Tmax)−(3)−(6)} to a maximum value {Vtune_coarse(Tmax)+(2)}. Again, assuming the parameter (6) is approximately equal to the parameter (4) in FIG. 3, Vtune_range_lo is seen to be less than Vtune_range.

For intermediate values of T between Tmin and Tmax, the variation of Vtune over temperature is expected to be similarly reduced due to the features described above.

One of ordinary skill in the art will thus appreciate that by making Vtune_coarse temperature-dependent in the manner described, the total variation of Vtune over temperature during fine tuning mode may be decreased. This allows the frequency synthesizer 400 to, e.g., maintain linear operation using a lower supply voltage than may be supported by the prior art synthesizer 100.

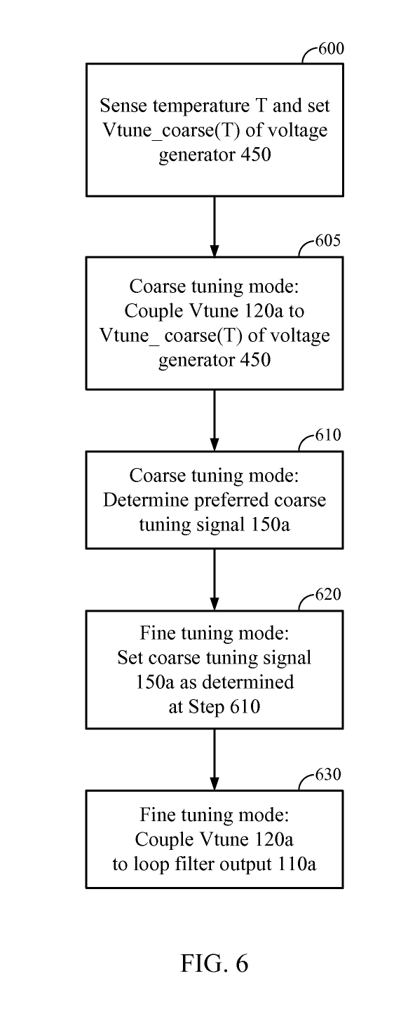

FIG. 6 depicts an exemplary embodiment of a method according to the present disclosure. Note the method depicted is intended for illustrative purposes only, and is not meant to limit the scope of the present disclosure to any particular method explicitly described.

In FIG. 6, at step 600, the temperature T is sensed, and the voltage Vtune_coarse(T) of voltage generator 450 is set in accordance with the measured temperature T. In an exemplary embodiment, the temperature T may be measured using a temperature sensor 480 such as depicted in FIG. 4.

At step 605, the three-way switch 120 couples Vtune to a signal 460a, or Vtune_coarse(T), generated by the Vtune_coarse(T) voltage generator 450. Vtune_coarse(T) voltage generator 450 may implement the temperature-dependent voltage generation techniques for Vtune_coarse(T) described earlier herein.

At step 610, the coarse tuning mode bank selector 150 determines the preferred coarse tuning signal.

At step 620, the coarse tuning mode bank selector 150 sets the coarse tuning signal 150a to be the preferred coarse tuning signal determined at step 181.

At step 630, the switch 120 couples the Vtune to the output 110a of a loop filter (LPF) 110, which may also coupled to a phase-frequency detector/charge pump (PFD/CP) 105 as shown in FIG. 4.

The techniques described herein may be implemented in hardware, software, firmware, or any combination thereof. If implemented in hardware, the techniques may be realized using digital hardware, analog hardware or a combination thereof. If implemented in software, the techniques may be realized at least in part by a computer-program product that includes a computer readable medium on which one or more instructions or code is stored.

By way of example, and not limitation, such computer-readable media can comprise RAM, such as synchronous dynamic random access memory (SDRAM), read-only memory (ROM), non-volatile random access memory (NVRAM), ROM, electrically erasable programmable read-only memory (EEPROM), erasable programmable read-only memory (EPROM), FLASH memory, CD-ROM or other optical disk storage, magnetic disk storage or other magnetic storage devices, or any other tangible medium that can be used to carry or store desired program code in the form of instructions or data structures and that can be accessed by a computer.

The instructions or code associated with a computer-readable medium of the computer program product may be executed by a computer, e.g., by one or more processors, such as one or more digital signal processors (DSPs), general purpose microprocessors, ASICs, FPGAs, or other equivalent integrated or discrete logic circuitry.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

A number of aspects and examples have been described. However, various modifications to these examples are possible, and the principles presented herein may be applied to other aspects as well. These and other aspects are within the scope of the following claims.

1. A method for tuning an output frequency of a voltage-controlled oscillator (VCO), the method comprising setting a fine tuning signal Vtune for the VCO during a coarse tuning mode, and determining a preferred coarse tuning signal for the VCO during the coarse tuning mode, the method further comprising:
sensing a temperature; and
setting the fine tuning input signal Vtune during the coarse tuning mode based on the sensed temperature.

2. The method of claim 1, further comprising:
setting the coarse tuning signal for the VCO as the preferred coarse tuning signal; and
determining a fine tuning input signal for the VCO during a fine tuning mode.

3. The method of claim 1, the sensing the temperature comprising sensing a temperature of the VCO circuit during coarse tuning mode.

4. The method of claim 1, the fine tuning input signal Vtune being a digital signal, the setting the fine tuning input signal Vtune based on the sensed temperature comprising:
digitally mapping the sensed temperature to a digital output signal Vtune_coarse(T); and
setting the fine tuning input signal Vtune as the digital output signal Vtune_coarse(T).

5. The method of claim 1, the fine tuning input signal Vtune being an analog signal, the setting the fine tuning input signal Vtune based on the sensed temperature comprising:
digitally mapping the sensed temperature to a digital output signal Vtune_coarse(T)_digital;
converting the digital output signal Vtune_coarse(T)_digital to an analog signal Vtune_coarse(T); and
setting the fine tuning input signal Vtune as the digital output signal Vtune_coarse(T).

6. The method of claim 5, the digitally mapping comprising:
searching for the sensed temperature as an input entry in a look-up table; and
generating the digital output signal Vtune_coarse(T)_digital as an output entry in the look-up table corresponding to the input entry.

7. The method of claim 5, the digitally mapping comprising:
generating the digital output signal Vtune_coarse(T)_digital based on the sensed temperature according to a predetermined V-T characteristic.

8. The method of claim 7, the predetermined V-T characteristic prescribing V as being a monotonically increasing function of T.

9. An apparatus for tuning an output frequency of a voltage-controlled oscillator (VCO), the VCO accepting a fine tuning voltage Vtune and a coarse tuning signal for controlling the output frequency of the VCO, the apparatus comprising:
a temperature sensor for measuring a temperature T; and
a voltage generator for generating a voltage Vtune_coarse(T) based on the measured temperature T, the VCO accepting the voltage Vtune_coarse(T) as the fine tuning voltage Vtune during a coarse tuning mode of the VCO.

10. The apparatus of claim 9, further comprising:
a coarse tuning bank selector for comparing an output frequency of the VCO with a reference frequency during the coarse tuning mode and determining an optimal setting for the coarse tuning signal of the VCO during the coarse tuning mode, the coarse tuning bank selector further providing the optimal setting for the coarse tuning signal of the VCO during a fine tuning mode of the VCO.

11. The apparatus of claim 10, the output signal of the VCO coupled to a comparator, the comparator comparing the frequency of the VCO output signal to a reference frequency, the output of the comparator coupled to the fine tuning voltage of the VCO during the fine tuning mode of the VCO.

12. The apparatus of claim 10, the output signal of the VCO coupled to a pulse counter/comparator, the pulse counter/comparator configured to measure a number of pulses in the VCO output signal over a time duration, the pulse counter/comparator further comparing the number of measured pulses to a predetermined reference number, the output of the pulse counter/comparator coupled to the coarse tuning voltage of the VCO during the fine tuning mode of the VCO.

13. The apparatus of claim 9, the temperature sensor sensing a temperature of the VCO circuit during the coarse tuning mode.

14. The apparatus of claim 9, the fine tuning voltage Vtune being a digital signal, the voltage generator digitally mapping the sensed temperature to a digital output signal Vtune_coarse(T).

15. The apparatus of claim 9, the fine tuning input signal Vtune being an analog signal, the apparatus further comprising a digital controller for digitally mapping the sensed temperature to a digital output signal Vtune_coarse(T)_digital, the voltage generator converting the digital output signal Vtune_coarse(T)_digital to an analog signal Vtune_coarse(T).

16. The apparatus of claim 15, the digital controller comprising:
a look-up table mapping a sensed temperature to a digital value of Vtune_coarse(T)_digital.

17. The apparatus of claim 15, the digital controller comprising:
a computing module for computing the digital output signal Vtune_coarse(T)_digital based on the sensed temperature according to a predetermined V-T characteristic.

18. The apparatus of claim 17, the predetermined V-T characteristic prescribing V as being a monotonically increasing function of T.

19. An apparatus for tuning an output frequency of a voltage-controlled oscillator (VCO), the VCO accepting a fine tuning voltage Vtune and a coarse tuning signal for controlling the output frequency of the VCO, the apparatus comprising:
means for sensing a temperature; and
means for setting the fine tuning input signal Vtune during the coarse tuning mode based on the sensed temperature.

20. The apparatus of claim 19, further comprising:
means for determining a fine tuning input signal for the VCO during a fine tuning mode.

21. The apparatus of claim 19, the fine tuning input signal Vtune being a digital signal, the means for setting the fine tuning input signal Vtune based on the sensed temperature comprising:
means for digitally mapping the sensed temperature to a digital output signal Vtune_coarse(T).

22. The apparatus of claim 19, the fine tuning input signal Vtune being an analog signal, the means for setting the fine tuning input signal Vtune based on the sensed temperature comprising:
means for digitally mapping the sensed temperature to a digital output signal Vtune_coarse(T)_digital;
means for converting the digital output signal Vtune_coarse(T)_digital to an analog signal Vtune_coarse(T); and
means for setting the analog signal Vtune_coarse(T) as Vtune during the coarse tuning mode.

23. A computer program product for tuning an output frequency of a voltage-controlled oscillator (VCO), the VCO accepting a fine tuning voltage Vtune and a coarse tuning signal for controlling the output frequency of the VCO, the product comprising:
computer-readable media comprising code for causing a computer to sense a temperature; and
computer-readable media comprising code for causing a computer to set the fine tuning input signal Vtune during the coarse tuning mode based on the sensed temperature.
